(19) United States
(12) Patent Application Publication
(10) Pub. No.: US 2004/0063007 A1
(43) Pub. Date: Apr. 1, 2004

(54) Precision-of-register measuring mark and measuring method

(76) Inventor: Satoshi Machida, Tokyo (JP)

Correspondence Address: RABIN & Berdo, PC, 1101 14TH STREET, NW, SUITE 500, WASHINGTON, DC, 20005, US

(21) Appl. No.: 10/668,257

(22) Filed: Sep. 24, 2003

Related U.S. Application Data
(60) Provisional application No. 60/413,942, filed on Sep. 27, 2002.

(51) Int. Cl. G03F 9/00; G03C 5/00; G01B 11/00

(52) U.S. Cl. 430/22; 430/30; 356/401

(57) ABSTRACT

According to the invention, the precision of register in dual exposure can be measured by measuring the length of the periphery of a register mark exposed twice when a positive resist is used and by measuring the length of the outer part of the register mark exposed once when a negative resist is used.

### BACKGROUND OF THE INVENTION

1. Field of the Invention

The present invention relates to a precision-of-register measuring mark and measuring method used for measuring an amount of relative displacement of semiconductor integrated circuit patterns of in a lithography step, which is one of steps for manufacturing a semiconductor integrated circuit apparatus.

2. Description of the Related Art

Processing for manufacturing a semiconductor integrated circuit apparatus (called LSI hereinafter) includes a deposition step, a lithography step, an etching step, and an implanting step. The deposition step generates a film containing desired materials for forming an LSI element on an LSI substrate (called wafer hereinafter). The lithography step transfers and forms an integrated-circuit pattern (called pattern hereinafter) on a high polymer (called resist hereinafter) film responsive to exposure light beams. The etching step uses a pattern of a resist film as a rejection film to etch a material film. The implanting step implants an impurity to the LSI in order to give a desired characteristic. By repeating the required number of the manufacturing processing including the deposition, lithography, etching and implanting steps, an LSI element can be constructed three-dimensionally and a desired LSI can be manufactured.

In the lithography step according to the invention, an original plate (called mask hereinafter) establishing a pattern by using chrome, for example, which is a material resistant to exposure light beams on a glass substrate is used. Then, an exposure apparatus including a reduced projection optical system is used for forming the pattern of the mask on the resist film on the wafer. Then, the resist is reacted. This transfer method is generally used as exposure processing. In the exposure processing, in order to construct an LSI element three dimensionally, the positions of the patterns on the mask must be in register with respect to the LSI element processed and formed on the wafer highly precisely in the previous step. For the register, a register mark is used. Register marks are provided on both mask and wafer on which patterns are transferred. However, in this case, the exposure apparatus must have a function for detecting the positions of the mask and the wafer by using the register marks, a function for measuring a position error and a function for moving the mask and/or the wafer to a desired position. Currently, a commercially-used exposure apparatus generally has these functions.

A latent image having a mask pattern is formed in the resist on the wafer to which the mask pattern is exposed with highly precise registration and is developed. Thus, the mask pattern is reproduced by the resist on the wafer with fidelity. In the lithography steps, an amount of relative displacement between the formed resist pattern and the LSI element pattern having been processed and formed in the previous step is measured, and the precision of register is checked in order to determine the step shipment. This can prevent a drain of defective items out of register, that is, exceeding the acceptable limits of the amount of relative displacement. The precision of register is an important step control matter.

Generally, precision-of-register measuring marks (called register measuring mark hereinafter) 31 may be used. The register measuring marks 31 include two types of mark including a reference mark 31a and a resist mark 31b as shown in FIG. 3. The reference mark 31a is processed concurrently with the processing of an LSI element in the proceeding steps. The resist mark 31b is formed with a resist through an exposure step and a developing step simultaneously with the forming of the resist pattern in the lithography step. A film 32 transfers patterns obtained in the lithography step. Now, a method will be described for measuring an amount of relative displacement by using the register measuring mark 31. By observing the register measuring mark 31 on a wafer by using an optical microscope, the image strength, that is, the brightness, of an object image in the X-axis direction is observed qualitatively as indicated by the reference numeral, 33. Here, with respect to a threshold value Ith of the image strength, the mark edge positions of the reference mark 31a may be P1 and P2 and the mark edge positions of the resist mark 31b may be P3 and P4.

An amount ΔP of relative displacement of the resist mark 31b with respect to the reference mark 31a can be calculated by:

Apparently from the equation, the centers of the marks are calculated from the mark edge position of the reference mark 31a and the mark edge position of the resist mark 31b. Then, the amount of the relative displacement of the mark is calculated from the difference in center of the marks. Similarly in the Y-axis direction, the edges of the register measuring marks are detected, and the positions are calculated. Thus, the amount of the two-dimensional displacement on the wafer can be recognized. If the amount of displacement is under the control standard for the step, the shipment from the step can be allowed.

However, the number of register measuring marks must be therefore equal to the number of lithography steps and, more precisely, must be equal to the number of times of the exposure of the wafer. Then, when a pattern is exposed to light multiple times at one exposure step, the register measuring marks occupy more in the limited exposure area and/or the measurement requires more time disadvantageously. However, recently, the multi-exposure tends to be required more as the degree of fineness of the pattern dimension increases. For example, in order to achieve the resolution beyond the limit of the ability of the exposure apparatus, a mask dividing a layout-designed pattern may be used for multi-exposure. Alternatively, a phase difference mask may be used in combination with a general chrome mask for multi-exposure.

FIG. 4 shows an example of the measurement of the degree of register precision in dual exposure. Reference marks 41a and 42a are formed simultaneously with the forming of an LSI element previously. In this example, the reference mark 41a and a resist mark 41b are located next to each other with a predetermined distance therebetween. A resist mark 41b contains a resist and is formed by being exposed simultaneously with the first resist pattern at the lithography step and being developed. The resist mark 42b contains a resist and is formed by being exposed simultaneously with the second resist pattern at the lithography step and being developed. A film 43 transfers the pattern at the lithography step. When the register measuring marks 41 and 42 on the wafer are observed by using an optical microscope, the image strength, which is the brightness of an object, of the register measuring marks 41 and 42 in the X-axis direction can be observed as the states 44 and 45, respectively. Here, with respect to a threshold value Ith of the image strength, the mark edge positions of the reference mark 41a are P11 and P12 and the mark edge positions of the reference mark 42a may be P21 and P22. The mark edge positions of the resist mark 41b are P13 and P14 and the mark edge positions of the resist mark 42b may be P23 and P24.

An amount ΔP1 of displacement due to the first exposure and an amount ΔP2 of displacement due to the second exposure can be calculated respectively by:

The same is true in the Y-axis direction,

In the conventional method for measuring register measuring marks equal to the number of times of exposure, the register measuring marks occupy more in the limited exposure area and/or the measurement requires more time disadvantageously.

### SUMMARY OF THE INVENTION

According to a first aspect of the invention, the precision of register in dual exposure can be measured by forming a register mark pattern of only a part to be exposed twice as a result of the two exposures in a register mark containing a positive resist and by measuring the length of the periphery of a register mark pattern having been exposed twice. According to a second aspect of the invention, the precision of register in dual exposure can be measured by forming a register mark pattern of a part to be exposed at least once as a result of the two exposures in a register mark containing a negative resist and by measuring the length of the periphery of a register mark pattern having been exposed twice.

### BRIEF DESCRIPTION OF THE DRAWINGS

FIG. 1 is a schematic diagram showing a precision-of-register measuring method in dual exposure according to a first embodiment of the invention;

FIG. 2 is a schematic diagram showing a precision-of-register measuring method in dual exposure according to a second embodiment of the invention;

FIG. 3 is a schematic diagram showing a precision-of-register measuring method according to a conventional technology; and

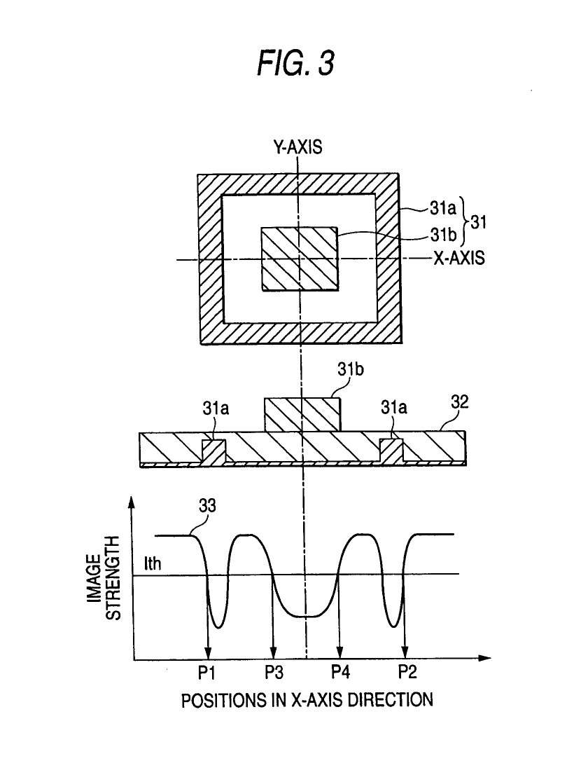

FIG. 4 is a schematic diagram showing a precision-of-register measuring method in dual exposure according to a conventional technology.

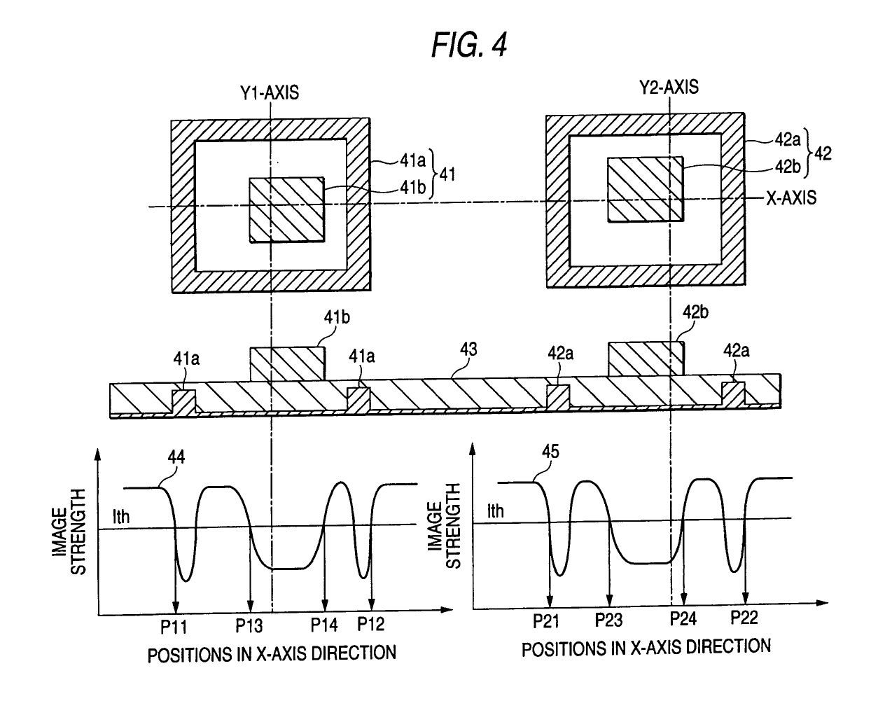

### DETAILED DESCRIPTION OF THE INVENTION

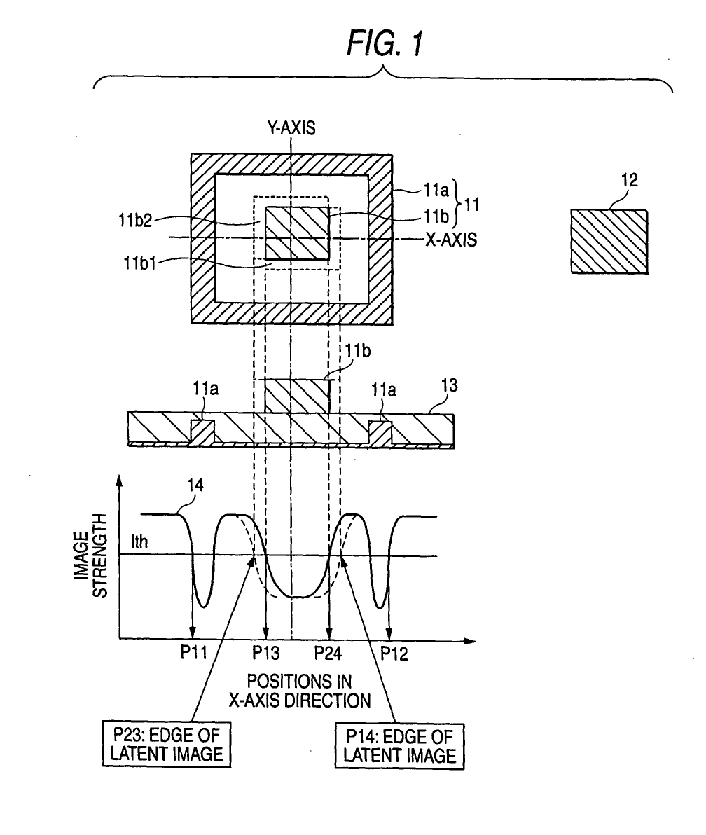

FIG. 1 is a schematic diagram showing a precision-of-register measuring method in dual exposure according to a first embodiment of the invention. In the first embodiment, an area responsive to exposure light beams contains a resist soluble to a developing solution, which is a so-called positive type resist. Register measuring marks 11 include a reference mark 11a formed simultaneously with the forming of an LSI element previously and a resist mark 11b formed with a resist through exposure and developing steps simultaneously with the forming of a resist pattern at the lithography step. Now, the resist mark 11b will be described in detail.

The resist mark uses a same simple-rectangular mask pattern 12. The resist mark pattern 12 is designed to locate at the same position on the mask to be used for the first and second exposure. Since the exposure in the lithography step is repeated twice, the resist before the developing step includes a latent image 11b1 of the resist mark as a result of the first exposure and a latent image 11b2 of the resist mark as a result of the second exposure. After undergoing the developing step, an AND (logical product) area of the latent images 11b1 and 11b2 is formed as the resist mark 11b1 in the positive type resist. A film 13 transfers the pattern in the lithography step.

When the register measuring marks 11 are observed by using an optical microscope, the image strength, which is the brightness of an object, in the X-axis direction can be observed as the solid line 14 in FIG. 1. Here, with respect to a threshold value Ith of the image strength, the mark edge positions of the reference mark 11a may be P11 and P12 and the mark edge positions of the resist mark 11b may be P13 and P24. The amount ΔP of displacement can be calculated by:

Focusing on the latent images in FIG. 1, the edge positions of the latent image as a result of the first exposure may be P13 and P14 while the edge positions of the latent image as a result of the second exposure may be P23 and P24. Therefore, the displacement amounts ΔP1_{Latent} and ΔP2_{Latent} of the latent images may be assumed as:

In this case, P14−P13=P24−P23. Therefore, from EQ4 and EQ5, the average displacement amount as a result of the first and second exposures is:

Therefore, the displacement amount ΔP obtained by EQ3 is the average displacement amount in dual exposure using a positive type resist.

As described above, according to the first embodiment, in dual exposure using a positive type resist, an average displacement amount can be obtained by measuring one register measuring mark once. Therefore, the share of the register measuring marks in the limited exposure area does not change and/or the measurement time does not change.

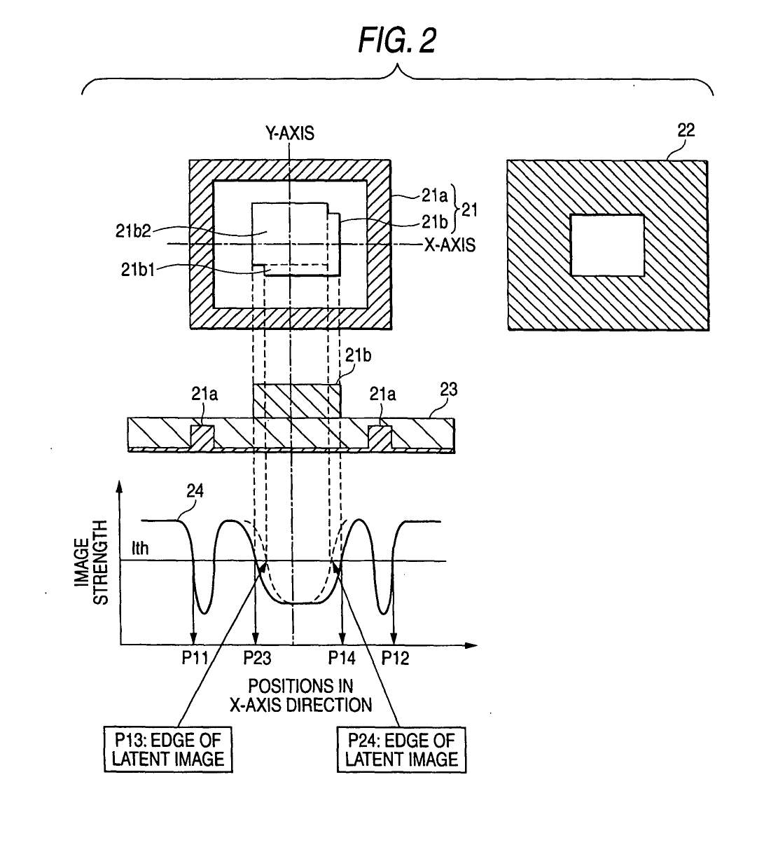

FIG. 2 is a schematic diagram showing a precision-of-register measuring method in dual exposure according to a second embodiment of the invention. In the second embodiment, an area responsive to exposure light beams contains a resist insoluble to a developing solution, which is a so-called negative type resist. Register measuring marks 21 include a reference mark 21a formed simultaneously with the forming of an LSI element previously and a resist mark 21b formed with a resist through exposure and developing steps simultaneously with the forming of a resist pattern at the lithography step. Now, the resist mark 21b will be described in detail.

The resist mark uses the same simple-rectangular mask pattern 22. The resist mark pattern 22 is designed to locate at the same position on the mask to be used for the first and second exposures. Since the exposure in the lithography step is repeated twice, the resist before the developing step includes a latent image 21b1 of the resist mark as a result of the first exposure and a latent image 21b2 of the resist mark as a result of the second exposure. After undergoing the developing step, an OR (logical add) area of the latent images 21b1 and 21b2 is formed as the resist mark 21b in the negative type resist. The shown solid line indicates the contour line. A film 23 transfers the pattern in the lithography step.

When the register measuring marks 21 are observed by using an optical microscope, the image strength, which is the brightness of an object, in the X-axis direction can be observed as the solid line 24 in FIG. 2. Here, with respect to a threshold value Ith of the image strength, the mark edge positions of the reference mark 21a may be P11 and P12 and the mark edge positions of the resist mark 21b may be P23 and P14. The amount ΔP of displacement can be calculated by:

Focusing on the latent images in FIG. 2, like the first embodiment, the edge positions of the latent image as a result of the first exposure may be P13 and P14 while the edge positions of the latent image as a result of the second exposure may be P23 and P24. Therefore, the displacement amounts ΔP1_{Latent} and ΔP2_{Latent} of the latent images may be assumed as:

In this case, P14−P13=P24−P23. Therefore, from EQ8 and EQ9, the average displacement amount as a result of the first and second exposures is:

Therefore, the displacement amount ΔP obtained by EQ7 is the average displacement amount in dual exposure using a negative type resist.

As described above, according to the second embodiment, in dual exposure using a negative type resist, an average displacement amount can be obtained by measuring one register measuring mark once. Therefore, the share of the register measuring mark in the limited exposure area does not change and/or the measurement time does not change.

What is claimed is:

1. A precision-of-register measuring mark, comprising:
a pair of register mark patterns spaced on a wafer; and
a resist pattern provided between the pair of register mark patterns and symmetrical in a direction of the arrangement of the pair of register mark patterns resulting from dual exposure.

2. A precision-of-register measuring mark according to claim 1, wherein the resist pattern has a simple rectangular form.

3. A precision-of-register measuring method, comprising the steps of:
forming a resist film on a wafer having a pair of spaced mark patterns;
forming a first rendering pattern by rendering on the wafer a mask pattern symmetrical in the direction of the arrangement of the pair of mark patterns as a result of a first exposure in register with the register mark pattern;
forming a second rendering pattern by rendering on the wafer the mask pattern as a result of a second exposure in register with the register mark pattern;
developing to form a resist pattern where the first rendering pattern and the second rendering pattern overlap; and
calculating the precision of register by (X1+X2)/2−(X3+X4)/2 where, in the register direction of the mask patterns, the coordinate of one side of one of the pair of register mark patterns is X1, the coordinate of one side of the other of the pair of register mark patterns and symmetrical to the one side of the one register mark pattern is X2, and the coordinates of two sides of the resist pattern are X3 and X4.

4. A precision-of-register measuring method according to claim 3, wherein the mark pattern has a simple rectangular form.
